(19) United States
(12) Patent Application Publication
(10) Pub. No.: US 2026/0362588 A1
(43) Pub. Date: Nov. 12, 2026

(54) INTERPOSER ON PCB SYSTEM ASSEMBLY

(71) Applicant: NVIDIA Corporation, Santa Clara, CA (US)

(72) Inventor: Adam Geboff, Campbell, CA (US)

(21) Appl. No.: 19/205,870

(22) Filed: May 12, 2025

(51) Int. Cl. H05K 1/02; H05K 3/10; H05K 3/341; H05K 3/46

(52) U.S. Cl. CPC H05K 1/0271; H05K 1/0201; H05K 3/108; H05K 3/341; H05K 3/4626; H05K 2201/068; H05K 2201/10378; H05K 2201/10522

(57) ABSTRACT

Systems and methods are provided for an interposer on a printed circuit board (PCB) system assembly. At least one embodiment relates to a PCB system assembly in which an interposer is directly connected to a PCB without an intervening substrate layer.

### TECHNICAL FIELD

The present disclosure relates to semiconductor packaging. In at least one embodiment, the present disclosure relates to printed circuit board (PCB) system assemblies.

### BACKGROUND

Printed circuit board (PCBs) serve as physical foundations and electrical foundations for electronic circuits. As both the physical foundations and the electrical foundations for electronic circuits, PCBs are found in various technologies. For example, in consumer electronics, PCBs are found in devices such as smartphones, laptops, and televisions. In automotive technologies, PCBs are found in electronic driver-assistance systems, engine control units, and infotainment systems. In artificial intelligence (AI) technologies, PCBs are found in various AI systems serving as physical foundations and electrical foundations for electronic components, such as graphics processing units (GPUs) and tensor processing units (TPUs). Given the prevalent use of PCBs in various technologies, advancements in PCB technology have widespread benefits across these various technologies.

### BRIEF DESCRIPTION OF THE DRAWINGS

The accompanying drawings are provided for purposes of illustration and not limitation. In the drawings, which are not necessarily drawn to scale, like numerals may describe similar components in different views.

FIG. 1 is a block diagram illustrating a printed circuit board (PCB) system assembly, according to at least one embodiment;

FIG. 2 is a block diagram illustrating a hybrid material stack, according to at least one embodiment;

FIG. 3 is a block diagram illustrating a hybrid material stack, according to at least one embodiment;

FIG. 4 is a block diagram illustrating a hybrid material stack, according to at least one embodiment;

FIG. 5 illustrates graphs of stresses measured in hybrid material stacks, according at least one embodiment;

FIG. 6 is a block diagram illustrating a system, according to at least one embodiment;

FIG. 7 is a flowchart illustrating a method for assembling a system, according to at least one embodiment;

FIG. 8 is a flowchart illustrating a method for assembling a system, according to at least one embodiment; and

FIG. 9 is a flowchart illustrating a method for assembling a system, according to at least one embodiment.

### DETAILED DESCRIPTION

Systems and methods are disclosed related to an interposer on a printed circuit board (PCB) system assembly. In at least one embodiment, a PCB system assembly includes an interposer directly connected to a PCB without an intervening substrate layer. This PCB system assembly provides for various technical advantages. For example, by directly connecting the interposer to the PCB and eliminating the intervening substrate layer, various technical problems associated with the substrate layer may be mitigated. Signal integrity between the interposer and the PCB is improved because signal losses associated with the substrate layer are eliminated or at least reduced. Thermal performance and electro-migration limits are also improved. Furthermore, the overall package size is reduced, facilitating the design of new architectures.

An “intervening substrate layer” refers to a package substrate that serves as an intermediate layer between an interposer and a PCB. A typical substrate layer has a CTE value between that of the interposer and the PCB and provides connections from connection bumps on the interposer (e.g., C4 bumps) to connection bumps on the PCB (e.g., BGA balls).

In at least one embodiment, a PCB system assembly includes a PCB with a controlled coefficient of thermal expansion (CTE), an interposer directly attached to the PCB, and one or more integrated circuit (IC) devices connected to the PCB through the interposer. The PCB incorporates a hybrid material stack that brings the overall CTE of the PCB within a threshold CTE, reducing and managing CTE mismatch between the interposer and the PCB. The PCB facilitates a breakout from the interposer in which electrical connections from the dense array of connection bumps on the interposer are routed to wider-spaced connections on the PCB. For example, the PCB provides routing escaping from relatively narrower-spaced traces on the interposer to relatively wider-spaced traces on the PCB.

CTE mismatch is reduced and managed to, in turn, reduce connection failures, delamination, and structural damage to a PCB system assembly. For example, a CTE mismatch occurs between a component made of a material with a relatively low CTE, such as silicon (e.g., 3 ppm/°C) and a component made of a material with a relatively high CTE, such as copper (e.g., 17 ppm/°C). In at least one embodiment, a PCB system assembly addresses CTE mismatch by including a PCB with a hybrid material stack that has at least one layer of a CTE controlling material (e.g., ceramic, glass, metal, aramid laminate) to reduce and manage CTE mismatch. Examples of suitable CTE controlling materials include, but are not limited to Aluminum Nitride with a CTE of 4.6 ppm/°C and Young's modulus of 320 GPa; Silicon Nitride with a CTE of 2.6 ppm/°C and Young's modulus of 310 GPa; and aramid-based materials with negative CTE values ranging from −2 to −6 ppm/°C. The CTE controlling material is selected through an analytical modeling approach that evaluates parameters (e.g., CTE, Young's modulus, Poisson's ratio, thickness, CTE weighting) of the CTE controlling material and other materials in the hybrid material stack. For example, a hybrid material stack includes at least one layer of conductive material (e.g., copper), at least one layer of bonding material or dielectric material, and at least one layer of the CTE controlling material. The parameters of the conductive material, the bonding material or dielectric material, and the CTE controlling material are evaluated to determine whether the CTE controlling material is effective at reducing and managing CTE mismatch for the hybrid material stack. Based on the analytical modeling approach, materials are selected for the hybrid material stack to bring the overall CTE of the hybrid material stack to within a threshold CTE.

In at least one embodiment, a threshold CTE is a CTE value or a CTE range based on a CTE target. For example, a threshold CTE is based on a CTE of an interposer. For an interposer made of silicon, the threshold CTE is a range (e.g., 8.5 ppm/°C −10.5 ppm/°C) based on the CTE of the interposer made of silicon (e.g., 3 ppm/°C). In at least one embodiment, a threshold CTE is based on an interface pitch of a PCB. In at least one embodiment, interface pitch refers to a spacing between connection points on electronic components such as interposers and PCBs. For example, an interface pitch may include a pitch of connection bumps between an interposer and a PCB. In at least one embodiment, the interface pitch of the PCB is between 150 micrometers (μm) and 180 μm, corresponding to high-speed input/output (HSIO) C4 bumps.

In at least one embodiment, the interface pitch of the PCB is between 180 μm and 195 μm, corresponding to core and power C4 bumps. In contrast, the interface pitch of an interposer with IC devices is between 12 μm and 23 μm, corresponding to μBumps. The interface pitch of the PCB facilitates a breakout from the fine pitch connections on the interposer to larger pitch connections on the PCB.

In at least one embodiment, the threshold CTE is proportional to the interface pitch of the PCB. The smaller the interface pitch of the PCB, the closer the threshold CTE is to a target CTE. The larger the interface pitch of the PCB, the farther the threshold CTE is from the target CTE. For example, for a silicon interposer, a first threshold CTE of a first PCB is closer to the CTE of the interposer (e.g., 3 ppm/°C) than a second threshold CTE of a second PCB based on a first interface pitch of the first PCB being smaller than a second interface pitch of the second PCB. A proportion by which the first threshold CTE is closer to the CTE of the interposer than the second threshold CTE is based on a proportion by which the first interface pitch is smaller than the second interface pitch. For example, in at least one embodiment, the threshold CTE for the PCB is 10 ppm/°C based on a target CTE that is the CTE value of an interposer made of silicon with (e.g., 3 ppm/°C). The threshold CTE is comparable to the CTE of an intervening substrate layer (e.g., 11±1 ppm/°C). In at least on embodiment, the threshold CTE is decreased (e.g., closer to the target CTE) or increased (e.g., farther from the target CTE) based on the interface pitch of the PCB. For example, a CTE threshold is determined using the formula X±(Y×Z), where X is a target CTE, Y is a proportionality constant, and Z is an interface pitch.

Internal stresses within a hybrid material stack are managed to help prevent delamination and structural failure. In at least one embodiment, a finite element analysis (FEA) modeling approach is used to analyze displacement, inter-layer stress, and delamination risk of a hybrid material stack. For example, displacement analysis of a hybrid material stack includes simulating physical displacement of layers within a PCB in X, Y, and Z axes based on temperature changes (e.g., ΔT=100 °C). Inter-layer stress analysis of the hybrid material stack includes evaluating normal and shear stresses at material boundaries, such as at the interfaces between materials with relatively higher differences in CTE values. Delamination risk analysis of the hybrid material stack includes identifying high stress regions that have potential to exceed the interlaminar bond strength or interlaminar shear strength of the materials of the hybrid material stack. The FEA modeling approach facilitates selection of materials and arrangement of the materials in the hybrid material stack to manage the internal stresses within the hybrid material stack.

In at least one embodiment, an effectiveness of a hybrid material stack in managing CTE mismatch is verified through testing. For example, thermal cycling tests involving repeated thermal cycles of heating and cooling (e.g., ΔT=100 °C) conducted on a test hybrid material stack to evaluate a durability of the test hybrid material stack and identify potential faults. Connection reliability testing involves assessing an integrity of connection bumps between an interposer and a PCB with a test hybrid material stack under various thermal conditions. Mechanical stress testing involves measuring mechanical properties such as flexural strength and modulus of a test hybrid material stack under various thermal conditions.

In at least one embodiment, a PCB system assembly facilitates a breakout from fine pitch connections on an interposer (e.g., 12-23 μm pitch) to larger pitch connections on a PCB (e.g., 150-180 μm pitch). To facilitate the breakout, the PCB is manufactured based on according to high-density interconnect (HDI) design rules to incorporate fine pitch connections into the PCB. For example, the PCB incorporates fine pitch via holes (e.g., 50-75 μm minimum laser via holes), fine pitch via pads (e.g., 90-200 μm minimum laser via pads), fine pitch line width (e.g., 12 μm copper width), and fine pitch spacing (e.g., 30-40 μm spacing). To facilitate the breakout, traces of the PCB are denser and thinner in lower layers of the PCB. For example, a L2 layer of a PCB has relatively wider traces with relatively more spacing between the traces. A L4 layer of the PCB has relatively thinner traces compared to the traces of the L2 layer and has relatively less spacing compared to the traces of the L2 layer. A L6 layer of the PCB has relatively thinner traces compared to the traces of the L2 layer and the L4 layer and has relatively less spacing compared to the traces of the L2 layer and the L4 layer. These differences in trace thickness and trace density accommodate a breakout while maintaining signal integrity and power distribution.

Implementing a breakout from fine pitch connections on an interposer to larger pitch connections on a PCB involves various considerations. For example, implementing a breakout involves layer stack planning in which multiple routing layers are utilized to accommodate high-density routing for the breakout. Implementing the breakout involves planning of vias with depth-to-diameter aspect ratios (e.g., 0.7:1-1.1:1) that facilitate the high-density routing of the breakout. Implementing the breakout involves signal integrity considerations as signal loss may occur in transitions between relatively thinner traces and relatively wider traces. Implementing the breakout involves power distribution considerations as power connections and ground connections are maintained in a relatively denser routing environment.

In at least one embodiment, a PCB system assembly is assembled based on a chip last flow. For example, an interposer assembly (e.g., chip on wafer) is assembled by attaching IC devices (e.g., Graphics Processing Units (GPUs), Large-Scale Integration (LSI) silicon dielets) to an interposer. The interposer assembly comprising the interposer and the IC devices is tested for functionality. In parallel, a PCB assembly (e.g., wafer on platform) is assembled by attaching electronic components to a PCB. The PCB assembly comprising the PCB and the electronic components is tested for functionality. The PCB assembly and the interposer assembly are attached to assemble a PCB system assembly. The PCB system assembly is tested for functionality. The chip last flow advantageously facilitates testing of the interposer assembly and the PCB assembly prior to assembling the PCB system assembly. Therefore, tested good chips are attached to tested good boards, reducing risk of yield loss.

In at least one embodiment, a PCB system assembly is assembled based on a chip first flow. For example, an interposer assembly (e.g., chip on wafer) is assembled by attaching IC devices (e.g., GPUs, LSI silicon dielets) to an interposer. The interposer assembly comprising the interposer and the IC devices are tested for functionality. A PCB assembly (e.g., wafer on platform) is assembled by attaching the interposer assembly to a PCB. The PCB assembly comprising the PCB and the interposer assembly is tested for functionality. Electronic components are attached to the PCB assembly to assemble a PCB system assembly. The chip first flow advantageously avoids components on a PCB that may interfere with attachment of an interposer assembly.

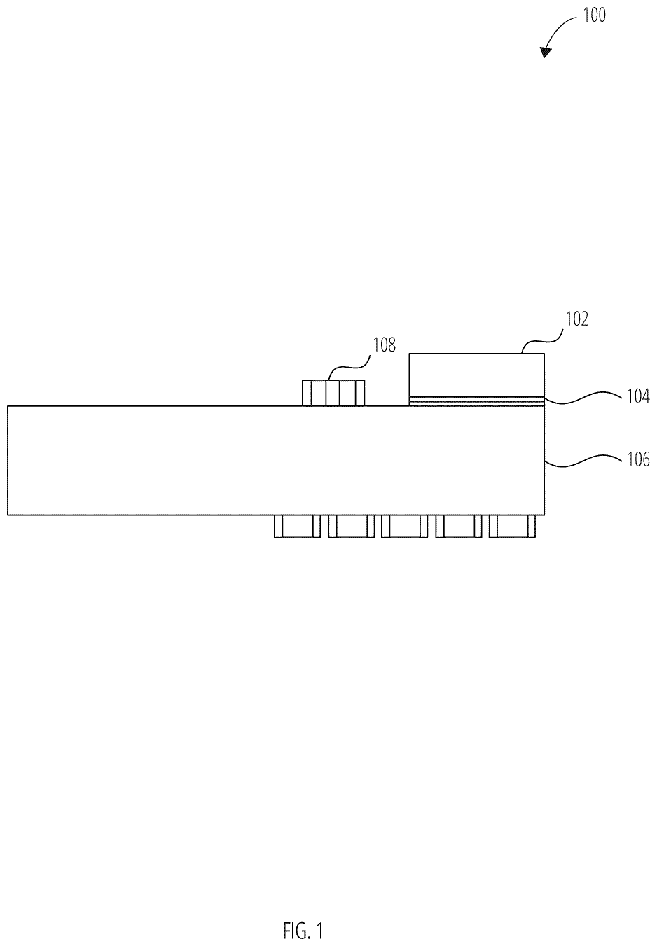

FIG. 1 is a block diagram illustrating an example PCB system assembly 100, according to at least one embodiment. It should be understood that this and other arrangements described herein are set forth only as examples. Other arrangements and elements (e.g., components, devices, machines, interfaces) may be used in addition to or instead of those shown, and some elements may be omitted altogether.

In FIG. 1, the PCB system assembly 100 includes an interposer 104 that is directly connected to a PCB 106 and facilitates connections between IC devices 102 (e.g., GPUs, HBM ASICs) and the PCB 106. For example, the IC devices 102 are directly connected to the interposer 104 via first connection bumps (e.g., μBumps). The interposer 104 is directly connected to the PCB 106 via second connection bumps (e.g., C4 bumps). The interposer 104 facilitates a transition in interface pitch from the first connection bumps (e.g., 12-23 μm pitch) to the second connection bumps (e.g., 150-180 μm pitch). Without an intervening substrate layer between the interposer 104 and the PCB 106, there is no transition in interface pitch from the second connection bumps to bumps of a larger pitch (e.g., 0.8 mm pitch). To facilitate the direct connection of the interposer 104 to the PCB 106, the PCB 106 supports pitch connections consistent with the second connection bumps (e.g., 150-180 μm pitch). The PCB 106 supports a breakout from the pitch connections consistent with the second connection bumps to connections consistent with electronic components 108 directly connected to the PCB 106.

As the interposer 104 and the PCB 106 are directly connected, there is no intervening substrate that dampens a difference in CTE between the interposer 104 and the PCB 106. For example, the interposer 104 has a first CTE (e.g., 3 ppm/°C) based on the material of the interposer 104 (e.g., silicon). To avoid a CTE mismatch between the interposer 104 and the PCB 106, the PCB 106 includes a hybrid material stack to bring the overall CTE of the PCB 106 to that of the interposer 104. The hybrid material stack includes a CTE controlling material to manage the overall CTE of the PCB 106. In at least one embodiment, the CTE controlling material is a prepreg material with a low CTE that reduces the overall CTE of the PCB 106 to within a threshold CTE of the CTE of the interposer 104. In at least one embodiment, the CTE controlling material is a ceramic material (e.g., Aluminum Nitride, Silicon Nitride). In at least one embodiment, the ceramic material is Aluminum Nitride with a CTE of approximately 4.6 ppm/°C and a Young's modulus of approximately 320 GPa. In at least one embodiment, the ceramic material is Silicon Nitride with a CTE of approximately 2.6 ppm/°C and a Young's modulus of approximately 310 GPa. These ceramic materials are selected for their ability to reduce the overall CTE of the hybrid material stack due to their low CTE values and high Young's modulus values. In at least one embodiment, the CTE controlling material is a glass material. In at least one embodiment, the CTE controlling material is an aramid laminate material. In at least one embodiment, the CTE controlling material is a metal material (e.g., Invar Copper, Molybdenum Copper). Controlling distribution of conductive layers (e.g., copper) throughout the hybrid material stack also manages the overall CTE of the PCB 106.

FIG. 1 illustrates improvements in package size of the PCB system assembly 100. Without an additional substrate layer, the PCB system assembly 100 has a reduced package height, reducing the overall package size of the PCB system assembly 100. With improved thermal performance, the PCB system assembly 100 foregoes a packaging lid or other temperature control mechanism, which also contributes to the reduction in the overall package size of the PCB system assembly 100. Without the additional substrate layer, multiple interposers may be organized more closely on the PCB 106, which also contributes to the reduction in the overall package size of the PCB system assembly 100.

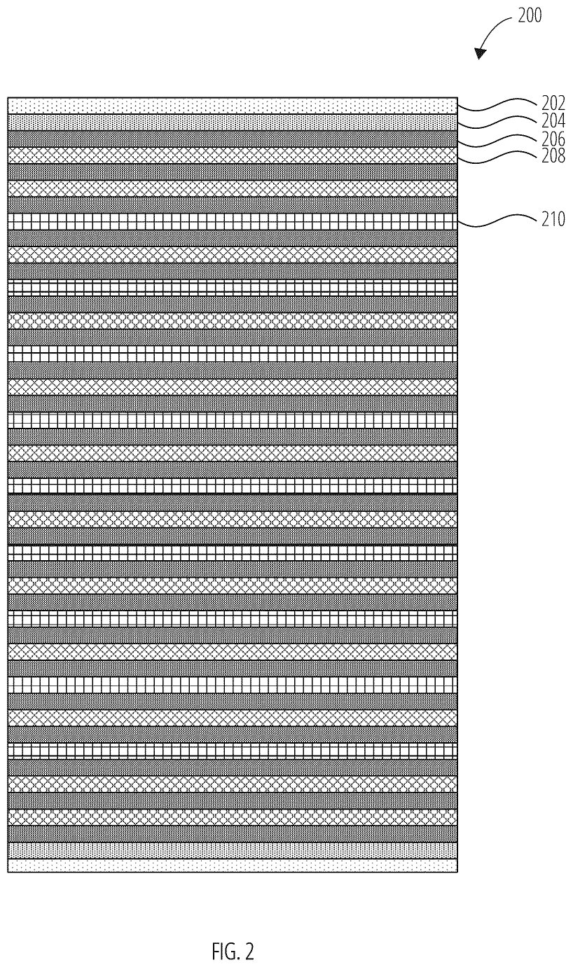

FIG. 2 is a block diagram illustrating an example hybrid material stack 200, according to at least one embodiment. In a PCB system assembly, a PCB includes, for example, the hybrid material stack 200, which includes layers of materials serving various functions. The hybrid material stack 200 includes outer layers 202 that provide protection and serve as external surfaces of the PCB. In at least one embodiment, the outer layers 202 are silkscreen layers and are made of a non-conductive epoxy. Within the hybrid material stack 200, solder mask layers 204 provide electrical insulation for the PCB. In at least one embodiment, the solder mask layers 204 are made of an epoxy resin. Within the hybrid material stack, conductive layers 206 provide electrical connectivity and power distribution. In at least one embodiment, the conductive layers 206 are made of copper. Within the hybrid material stack, bonding layers 208 bond the layers of the hybrid material stack together, providing mechanical stability. The bonding layers 208 include dielectric materials that act as electrical insulators for the conductive layers 206. In at least one embodiment, the bonding layers 208 are made of prepreg materials. Within the hybrid material stack, CTE controlling layers 210 manage the overall CTE of the PCB. In at least one embodiment, the CTE controlling layers 210 are made of a specialized prepreg material, a ceramic material, a glass material, an aramid material, or a metal material.

To manage the overall CTE of the hybrid material stack 200 and the PCB, a CTE controlling material is selected for the CTE controlling layers 210 based on an analytical model calculating the overall CTE of the hybrid material stack 200 from weighted CTE contributions from the layers in the hybrid material stack 200. The weighted CTE contribution for a material in the hybrid material stack 200 are calculated based on the CTE of the material multiplied by a weighting for the material. The weighting for the material is calculated based on the Young's modulus of the material and its relative thickness compared to the thickness of the hybrid material stack. For example, a formula for calculating a weighting for a material in the hybrid material stack 200 is: (YM×Z)/Σ(YMₙ x Zₙ) where YM is the Young's modulus of the material, Z is a thickness of the material, and Σ(YMₙ x Zₙ) is a sum of Young's modulus multiplied by thickness for all materials in the hybrid material stack 200. A CTE contribution for the material is calculated by multiplying the CTE of the material with the weighting.

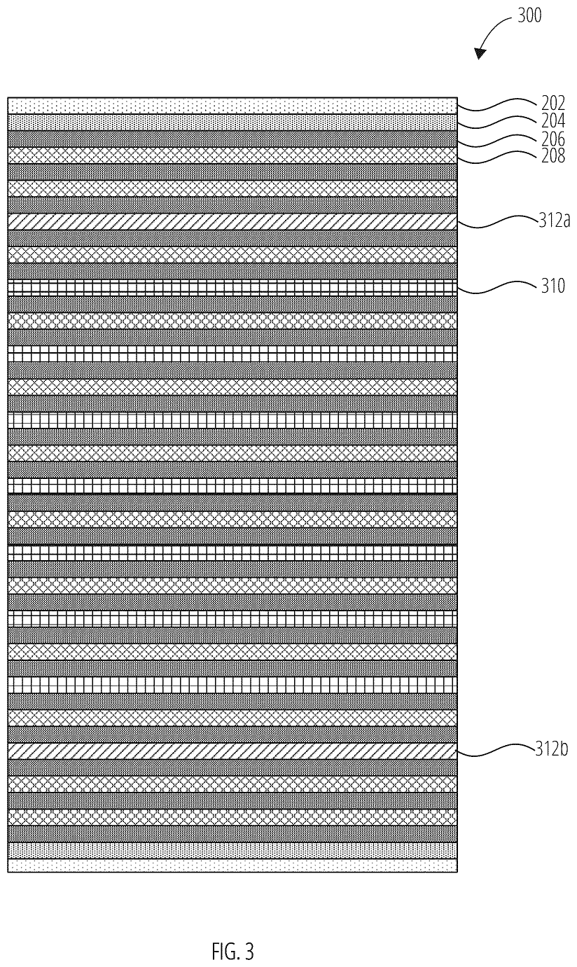

FIG. 3 is a block diagram illustrating an example hybrid material stack 300, according to at least one embodiment. In a PCB system assembly, a PCB includes, for example, the hybrid material stack 300, which includes layers of materials serving various functions. The hybrid material stack 300 includes, for example, outer layers 202 that provide protection and serve as external surfaces of the PCB, solder mask layers 204 that provide electrical insulation for the PCB, conductive layers 206 that provide electrical connectivity and power distribution, and bonding layers 208 that bond the layers of the hybrid material stack together, providing mechanical stability. Within the hybrid material stack, first CTE controlling layers 310 manage the overall CTE of the PCB. In at least one embodiment, the first CTE controlling layers 310 are made of a specialized prepreg material, a ceramic material, a glass material, an aramid material, or a metal material. Within the hybrid material stack, second CTE controlling layers 312a, 312b manage the overall CTE of the PCB. In at least one embodiment, the second CTE controlling layers 312, 312b are made of a specialized prepreg material, a ceramic material, a glass material, an aramid material, or a metal material.

In FIG. 3, the second CTE controlling layers 312a, 312b have lower CTE values than the first CTE controlling layers 310. By having lower CTE values than the first CTE controlling layers 310, the second CTE controlling layers 312a, 312b manage the overall CTE of the PCB by lowering the overall CTE of the PCB. As illustrated by an analytical modeling approach, the effect on the overall CTE by the second CTE controlling layers 312a, 312b is increased or lowered by increasing or lowering the thickness of the second CTE controlling layers 312a, 312b. In at least one embodiment, the CTE contribution of the second CTE controlling layers 312a, 312b are increased by increasing thickness of the second CTE controlling layers 312a, 312b. By increasing the CTE contribution of the second CTE controlling layers 312a, 312b, the overall CTE of the PCB is lowered further.

For example, in at least one embodiment, the hybrid material stack 300 includes copper layers (CTE: 18.9 ppm/°C, Young's modulus: 96 GPa) with a total thickness of 834 μm for the conductive layers 206, prepreg layers (CTE: 7 ppm/°C, Young's modulus: 16.5 GPa) with a total thickness of 1,354 μm for the bonding layers 208 and the first CTE controlling layers 310, and two Aluminum Nitride layers (CTE: 4.6 ppm/°C, Young's modulus: 320 GPa) with a total thickness of 500 μm for the second CTE controlling layers 312 a, 312 b. Based on an analytical modeling approach, this configuration achieves an overall CTE of approximately 9.17 ppm/°C, which is within a threshold CTE of 10 ppm/°C.

Internal stresses develop between layers of material with different CTE values. In at least one embodiment, a finite element analysis modeling calculates the displacement, inter-layer stress, and delamination risk of the hybrid material stack 300. Based on these factors, the second CTE controlling layers 312a, 312b are positioned in the hybrid material stack 300 where these factors are minimized. For example, placing the second CTE controlling layers 312a, 312b near the outer layers 202 of the hybrid material stack 300 avoids high inter-layer stress within the middle of the hybrid material stack 300.

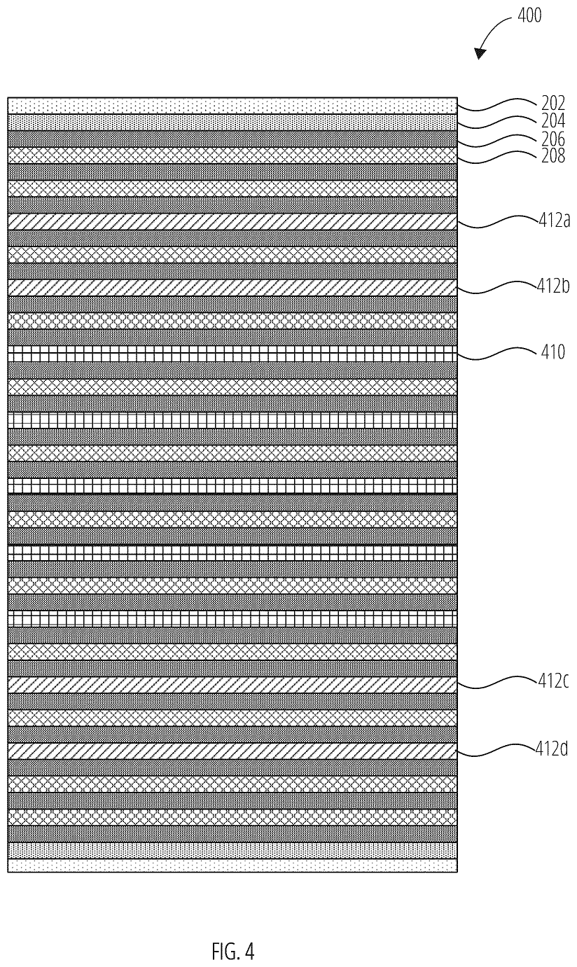

FIG. 4 is a block diagram illustrating an example hybrid material stack 400, according to at least one embodiment. In a PCB system assembly, a PCB includes, for example, the hybrid material stack 300, which includes layers of materials serving various functions. The hybrid material stack 300 includes, for example, outer layers 202 that provide protection and serve as external surfaces of the PCB, solder mask layers 204 that provide electrical insulation for the PCB, conductive layers 206 that provide electrical connectivity and power distribution, and bonding layers 208 that bond the layers of the hybrid material stack together, providing mechanical stability. Within the hybrid material stack, first CTE controlling layers 410 manage the overall CTE of the PCB. In at least one embodiment, the first CTE controlling layers 410 are made of a specialized prepreg material, a ceramic material, a glass material, an aramid material, or a metal material. Within the hybrid material stack, second CTE controlling layers 412a, 412b, 412c, 412d manage the overall CTE of the PCB. In at least one embodiment, the second CTE controlling layers 412a, 412b, 412c, 412d are made of a specialized prepreg material, a ceramic material, a glass material, an aramid material, or a metal material.

In FIG. 4, the second CTE controlling layers 412a, 412b, 412c, 412d manage the overall CTE of the PCB by bringing the overall CTE of the PCB towards a target CTE value. The CTE contribution of the second CTE controlling layers 412a, 412b, 412c, 412d are increased by increasing a number of the second CTE controlling layers 412a, 412b, 412c, 412d, thereby increasing the overall thickness of the second CTE controlling layers 412a, 412b, 412c, 412d.

In at least one embodiment, CTE controlling materials used in the hybrid material stack 400 have very low or near-zero CTE values or even negative CTE values. As internal stresses between layers of material with relatively high differences in CTE values increase the risk of delamination, the distribution of layers in the hybrid material stack 400 avoids positioning layers with relatively high positive CTE values next to layers with relatively high negative CTE values. In at least one embodiment, the first CTE controlling layers 410 and the second CTE controlling layers 412a, 412b, 412c, 412d are made of materials with negative CTE values. In at least one embodiment, the first CTE controlling layers 410 is made of a material with a CTE value within the range of CTE values of the materials of the conductive layers 206, the bonding layers 208, and the second CTE controlling layers 412a, 412b, 412c, 412d to avoid relatively large differences in CTE value between layers.

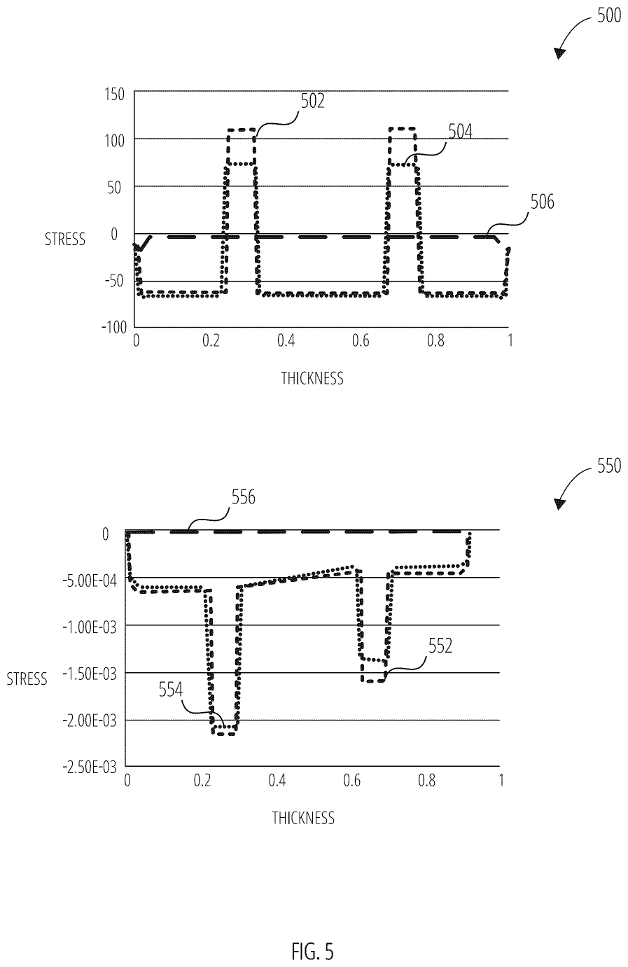

FIG. 5 illustrates example graphs 500, 550 of stresses measured in hybrid material stacks, according to at least one embodiment. Graph 500 illustrates measurements of normal stress on the y-axis at locations (e.g., thicknesses) through hybrid material stacks on the x-axis. The normal stress of a point of reference hybrid material stack 506 illustrates how a solid stack of materials with minimal differences in CTE value experiences minimal values of normal stress throughout the stack. The normal stress of a hybrid material stack 502 using a first CTE controlling material (e.g., Silicon Nitride) illustrates how normal stresses are exerted in one direction (e.g., positive normal stress) at locations corresponding with layers of the first CTE controlling material and in another direction (e.g., negative normal stress) at other locations in the stack. The normal stress of a hybrid material stack 504 using a second CTE controlling material (e.g., Aluminum Nitride) illustrates how normal stresses are exerted in one direction (e.g., positive normal stress) at locations corresponding with layers of the second CTE controlling material and in another direction (e.g., negative normal stress) at other locations in the stack. As illustrated in the graph 500, the overall normal stress exerted in the hybrid material stack 504 using the second CTE controlling material is less than that of the hybrid material stack 502 using the first CTE controlling material.

Graph 550 illustrates measurements of shear stress on the y-axis at locations through hybrid material stacks on the x-axis. The shear stress of a point of reference hybrid material stack 556 illustrates how a solid stack of materials with minimal differences in CTE value experiences minimal values of shear stress throughout the stack. The shear stress of a hybrid material stack 554 using a first CTE controlling material (e.g., Silicon Nitride) illustrates how shear stresses increase at locations corresponding with layers of the first CTE controlling material. The shear stress of a hybrid material stack 552 using a second CTE controlling material (e.g., Aluminum Nitride) illustrates how shear stresses increase at locations corresponding with layers of the second CTE controlling material. As illustrated in the graph 550, the overall shear stress exerted in the hybrid material stack 554 using the second CTE controlling material is less than that of the hybrid material stack 552 using the first CTE controlling material.

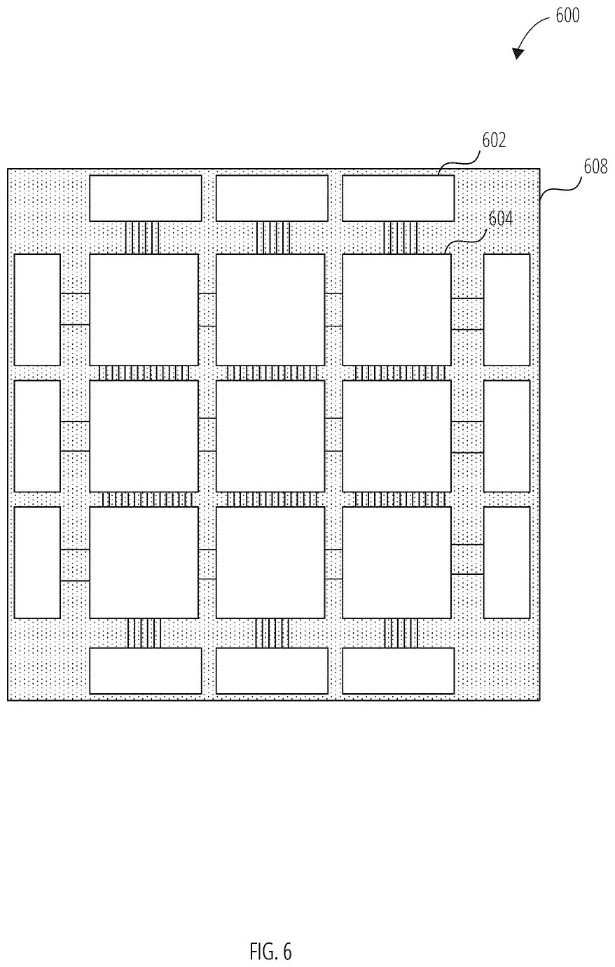

FIG. 6 is a block diagram illustrating an example system 600, according to at least one embodiment. The system 600 includes interposers 604 directly connected to a PCB 608 that electronically couples the interposers 604 to electronic components 602 on the PCB 608. In the system 600, elimination of intervening substrate layers between the interposers 604 and the PCB 608 allows for the interposers 604 to be arranged more closely together than they would with intervening substrate layers. For example, without intervening substrate layers, the footprint of the interposers 604 is reduced from 97×83 mm to 68×60mm, allowing for the PCB 608 to be reduced in size by approximately 50% while accommodating the interposers 604.

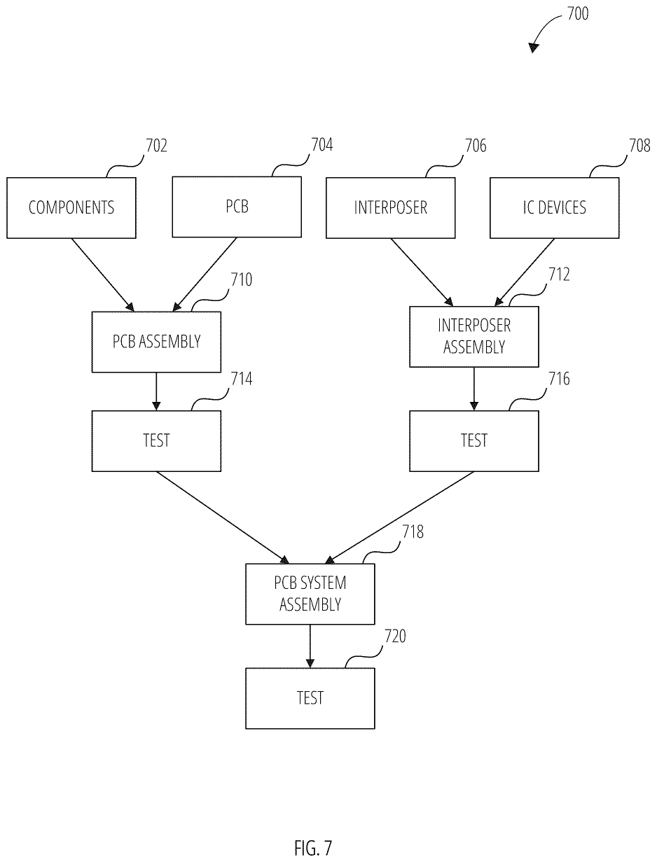

FIG. 7 is a flowchart illustrating an example method 700, according to at least one embodiment. At operation 710, components 702 (e.g., voltage regulators, interfaces, power components, electronic components) and a PCB 704 are attached to form a PCB assembly. In at least one embodiment, the components 702 and the PCB 704 are attached using a thermal compression bonding process in which heat and pressure are applied to form connections between the components 702 and the PCB 704. In at least one embodiment, the components 702 and the PCB 704 are attached using a reflow assembly process in which solder is melted to create connections between the components 702 and the PCB 704. At operation 714, the PCB assembly is tested for functionality. In a parallel process, at operation 712, an interposer 706 and IC devices 708 (e.g., GPUs, HBM ASICs, LSI dielets) are attached to form an interposer assembly. In at least one embodiment, the interposer 706 and the IC devices 708 are attached using a thermal compression bonding process. In at least one embodiment, the interposer 706 and the IC devices 708 are attached using a reflow assembly process. At operation 716, the interposer assembly is tested for functionality. At operation 718, the tested PCB assembly and the tested interposer assembly are attached to form a PCB system assembly. At operation 720, the PCB system assembly is tested for functionality.

In FIG. 7, the method 700 illustrates a chip last process in which the interposer assembly and the PCB assembly are assembled in parallel and then attached to form the PCB system assembly. The chip last process advantageously provides for testing of the interposer assembly and the PCB assembly prior to assembling the PCB system assembly, which reduces yield loss risk by attaching tested interposer assemblies with tested PCB assemblies. Furthermore, the IC devices 708 are subjected to relatively fewer processes involving heat and pressure.

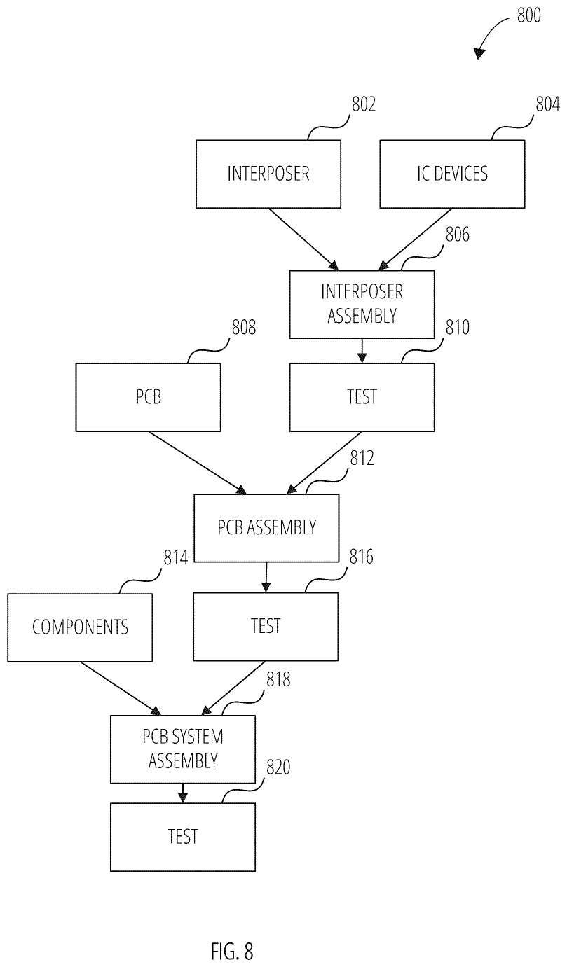

FIG. 8 is a flowchart illustrating an example method 800, according to at least one embodiment. At operation 806, an interposer 802 and IC devices 804 (e.g., GPUs, HBM ASICs, LSI dielets) are attached to form an interposer assembly. In at least one embodiment, the interposer 802 and the IC devices 804 are attached using a thermal compression bonding process in which heat and pressure are applied to form connections between the interposer 802 and the IC devices 804. In at least one embodiment, the interposer 802 and the IC devices 804 are attached using a reflow assembly process in which solder is melted to create connections between the interposer 802 and the IC devices 804. At operation 810, the interposer assembly is tested for functionality. At operation 812, a PCB 808 is attached to the tested interposer assembly to form a PCB assembly. In at least one embodiment, the PCB 808 and the interposer assembly are attached using a thermal compression bonding process. In at least one embodiment, the PCB 808 and the interposer assembly are attached using a reflow assembly process. At operation 816, the PCB assembly is tested for functionality. At operation 818, components 814 (e.g., voltage regulators, interfaces, power components, electronic components) are attached to the tested PCB assembly to form a PCB system assembly. In at least one embodiment, the components 814 and the PCB assembly are attached using a thermal compression bonding process. In at least one embodiment, the components 814 and the PCB assembly are attached using a reflow assembly process. At operation 820, the PCB system assembly is tested for functionality.

In FIG. 8, the method 800 illustrates a chip first process in which the elements of the PCB system assembly are attached and tested sequentially. The chip first process advantageously avoids situations where components on a PCB assembly interfere with attachment of the PCB assembly to an interposer assembly, simplifying the assembly process.

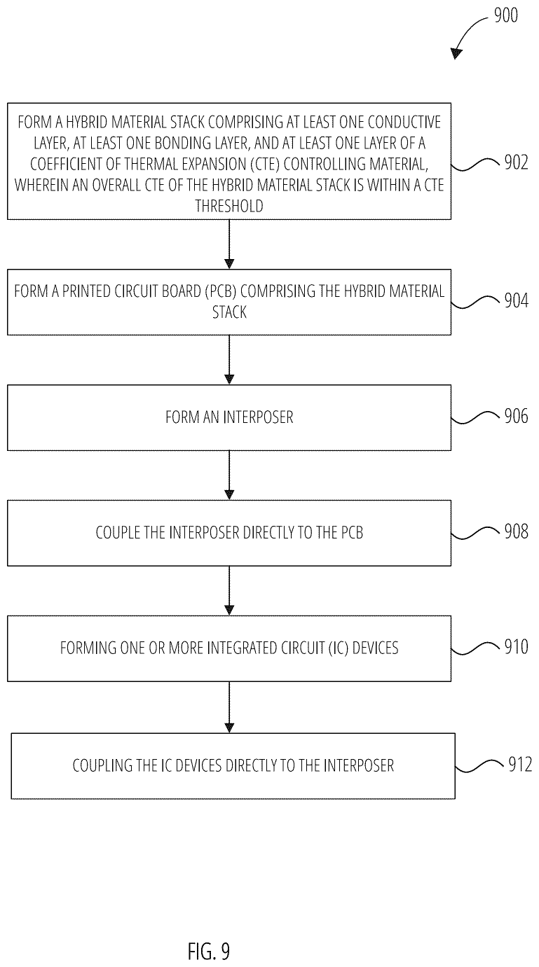

FIG. 9 is a flowchart illustrating an example method 900, according to at least one embodiment. At operation 902, a hybrid material stack is formed comprising at least one conductive layer, at least one bonding layer, and at least one layer of a CTE controlling material, wherein an overall CTE of the hybrid material stack is within a CTE threshold. In at least one embodiment, the hybrid material stack is formed based on the descriptions provided with respect to FIGS. 2-4. At operation 904, a PCB is formed comprising the hybrid material stack. In at least one embodiment, the PCB is formed using a high-density interconnect fabrication process in which laser drilling is employed to create microvias connecting the layers of the PCB. The microvias are metallized through copper deposition and plating to establish electrical connections between the layers of the PCB. Conductive traces are formed using by using laser direct imaging, providing for fine trace widths and spacing. In at least one embodiment, the PCB is formed using a full-additive process, a semi-additive process, or a modified semi-additive process. For example, in a full-additive process, conductive traces are formed on a conductive layer by depositing copper onto an insulating substrate on which a circuit pattern has been imaged. In a semi-additive process, copper is deposited on a substrate, and conductive traces are patterned from the copper layer on the substrate. Copper is further removed through etching to achieve fine trace widths and spacings. In a modified semi-additive process, a photostructurable resist is used to establish conductive trace patterns, providing for thickening of conductive traces through electroplating. Fine trace widths and spacings are achieved after the electroplating through etching to remove excess copper. At operation 906, an interposer is formed. In at least one embodiment, the interposer is formed by preparing a substrate, creating vias through the substrate, and adding a redistribution layer to enable horizontal electrical connections. At operation 908, the interposer is coupled directly to the PCB. In at least one embodiment, the interposer and the PCB are coupled based on descriptions provided with respect to FIGS. 7-8. At operation 910, one or more IC devices are formed. At operation 912, the IC devices are coupled directly to the interposer. In at least one embodiment, the IC devices and the interposer are coupled based on descriptions provided with respect to FIGS. 7-8.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

The subject matter of the present disclosure is described with specificity herein to meet statutory requirements. However, the description itself is not intended to limit the scope of this disclosure. Rather, the inventors have contemplated that the claimed subject matter might also be embodied in other ways, to include different steps or operations or combinations of steps or operations similar to the ones described in this document, in conjunction with other present or future technologies. Moreover, although the terms “step” and/or “block” and/or “operation” may be used herein to connote different elements of methods employed, the terms should not be interpreted as implying any particular order among or between various steps herein disclosed unless and except when the order of individual steps is explicitly described.

Many modifications and other embodiments of the present inventions set forth herein will come to mind to one skilled in the art to which these inventions pertain having the benefit of the teachings presented in the foregoing descriptions and the associated drawings. Therefore, it is to be understood that the present inventions are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

### EXAMPLES

Specific examples are now described. In view of the above-described implementations of subject matter this application discloses the following list of examples, wherein one feature of an example in isolation or more than one feature of an example, taken in combination and, optionally, in combination with one or more features of one or more further examples are further examples also falling within the disclosure of this application.

Example 1 is a system comprising a printed circuit board (PCB); an interposer directly coupled to the PCB; and one or more integrated circuit (IC) devices coupled to the PCB through the interposer.

In Example 2, the subject matter of Example 1 comprises wherein the PCB comprises a hybrid material stack, the hybrid material stack comprising at least one layer of a coefficient of thermal expansion (CTE) controlling material that causes an overall CTE of the PCB to be within a threshold CTE of a CTE of the interposer.

In Example 3, the subject matter of Example 2 comprises wherein the hybrid material stack further comprises conductive layers comprising a conductive material alternating with bonding layers comprising a dielectric material, the conductive layers and the bonding layers between at least two layers of the CTE controlling material.

In Example 4, the subject matter of Example 3 comprises wherein the hybrid material stack is arranged based on CTE contributions of the conductive layers, the bonding layers, and the at least two layers of the CTE controlling material.

In Example 5, the subject matter of Examples 1-4 comprises a thickness of the CTE controlling material in the hybrid material stack is selected based on a CTE value and a Young's Modulus of the CTE controlling material.

In Example 6, the subject matter of Examples 1-5 comprises wherein the interposer is directly coupled to the PCB via connection bumps between the interposer and the PCB.

In Example 7, the subject matter of Examples 1-6 comprises wherein the PCB has a CTE within a threshold CTE corresponding with an interface pitch between the PCB and the interposer.

In Example 8, the subject matter of Examples 1-7 comprises wherein the PCB is formed using at least one of a full-additive fabrication process, a semi-additive fabrication process, or a modified semi-additive fabrication process.

In Example 9, the subject matter of Examples 1-8 comprises wherein the PCB provides routing escaping from the interposer with a first set of traces on a first layer to a second set of traces on a second layer, a first spacing between the first set of traces being smaller than a second spacing between the second set of traces.

Example 10 is a printed circuit board (PCB) assembly comprising: a hybrid material stack comprising at least one layer of a coefficient of thermal expansion (CTE) controlling material that causes an overall CTE of a PCB of the PCB assembly to be within a threshold CTE of a CTE of an interposer; and the interposer directly coupled to the hybrid material stack.

In Example 11, the subject matter of Example 10 comprises conductive layers comprising a conductive material alternating with bonding layers comprising a dielectric material, the conductive layers and the bonding layers between at least two layers of the CTE controlling material.

In Example 12, the subject matter of Examples 10-11 comprises wherein the at least one layer of the CTE controlling material comprises a negative CTE material.

In Example 13, the subject matter of Examples 10-12 comprises wherein the interposer is directly coupled to the hybrid material stack via connection bumps between the interposer and the hybrid material stack.

In Example 14, the subject matter of Examples 10-13 comprises wherein the PCB assembly has a CTE within a threshold CTE corresponding with an interface pitch of the PCB.

In Example 15, the subject matter of Examples 10-14 comprises one or more integrated circuit (IC) devices coupled to the interposer.

Example 16 is a method comprising: forming a hybrid material stack comprising at least one conductive layer, at least one bonding layer, and at least one layer of a coefficient of thermal expansion (CTE) controlling material, wherein an overall CTE of the hybrid material stack is within a CTE threshold; and forming a printed circuit board (PCB) comprising the hybrid material stack.

In Example 17, the subject matter of Example 16 comprises forming an interposer; and coupling the interposer directly to the PCB.

In Example 18, the subject matter of Example 17 comprises forming one or more integrated circuit (IC) devices; and coupling the one or more IC devices directly to the interposer.

In Example 19, the subject matter of Examples 17-18 comprises wherein the interposer is coupled directly to the PCB.

In Example 20, the subject matter of Examples 16-19 comprises wherein the PCB has a CTE within a threshold CTE corresponding with an interface pitch of the PCB.

Example 21 is at least one machine-readable medium including instructions that, when executed by processing circuitry, cause the processing circuitry to perform operations to implement any of Examples 1-20.

Example 22 is an apparatus comprising means to implement any of Examples 1-20.

Example 23 is a system to implement any of Examples 1-20.

Example 24 is a method to implement any of Examples 1-20.

What is claimed is:

1. A system comprising:
a printed circuit board (PCB);
an interposer directly coupled to the PCB; and
one or more integrated circuit (IC) devices coupled to the PCB through the interposer.

2. The system of claim 1, wherein the PCB comprises a hybrid material stack, the hybrid material stack comprising at least one layer of a coefficient of thermal expansion (CTE) controlling material that causes an overall CTE of the PCB to be within a threshold CTE of a CTE of the interposer.

3. The system of claim 2, wherein the hybrid material stack further comprises conductive layers comprising a conductive material alternating with bonding layers comprising a dielectric material, the conductive layers and the bonding layers between at least two layers of the CTE controlling material.

4. The system of claim 3, wherein the hybrid material stack is arranged based on CTE contributions of the conductive layers, the bonding layers, and the at least two layers of the CTE controlling material.

5. The system of claim 2, wherein a thickness of the CTE controlling material in the hybrid material stack is selected based on a CTE value and a Young's Modulus of the CTE controlling material.

6. The system of claim 1, wherein the interposer is directly coupled to the PCB via connection bumps between the interposer and the PCB.

7. The system of claim 1, wherein the PCB has a CTE within a threshold CTE corresponding with an interface pitch between the PCB and the interposer.

8. The system of claim 1, wherein the PCB is formed using at least one of a full-additive fabrication process, a semi-additive fabrication process, or a modified semi-additive fabrication process.

9. The system of claim 1, wherein the PCB provides routing escaping from the interposer with a first set of traces on a first layer to a second set of traces on a second layer, a first spacing between the first set of traces being smaller than a second spacing between the second set of traces.

10. A printed circuit board (PCB) assembly comprising:
a hybrid material stack comprising at least one layer of a coefficient of thermal expansion (CTE) controlling material that causes an overall CTE of a PCB of the PCB assembly to be within a threshold CTE of a CTE of an interposer; and
the interposer directly coupled to the hybrid material stack.

11. The PCB assembly of claim 10, the hybrid material stack further comprising:
conductive layers comprising a conductive material alternating with bonding layers comprising a dielectric material, the conductive layers and the bonding layers between at least two layers of the CTE controlling material.

12. The PCB assembly of claim 10, wherein the at least one layer of the CTE controlling material has a negative CTE value.

13. The PCB assembly of claim 10, wherein the interposer is directly coupled to the hybrid material stack via connection bumps between the interposer and the hybrid material stack.

14. The PCB assembly of claim 10, wherein the PCB assembly has a CTE within a threshold CTE corresponding with an interface pitch of the PCB.

15. The PCB assembly of claim 10, further comprising:
one or more integrated circuit (IC) devices coupled to the interposer.

16. A method comprising:
forming a hybrid material stack comprising at least one conductive layer, at least one bonding layer, and at least one layer of a coefficient of thermal expansion (CTE) controlling material, wherein an overall CTE of the hybrid material stack is within a CTE threshold; and
forming a printed circuit board (PCB) comprising the hybrid material stack.

17. The method of claim 16, further comprising:
forming an interposer; and
coupling the interposer directly to the PCB.

18. The method of claim 17, further comprising:
forming one or more integrated circuit (IC) devices; and
coupling the one or more IC devices directly to the interposer.

19. The method of claim 17, wherein the interposer is coupled directly to the PCB.

20. The method of claim 16, wherein the PCB has a CTE within a threshold CTE corresponding with an interface pitch of the PCB.
